(19) United States
(12) Patent Application Publication
(10) Pub. No.: US 2008/0296644 A1
(43) Pub. Date: Dec. 4, 2008

(54) CMOS IMAGE SENSORS AND METHODS OF FABRICATING SAME

(75) Inventors: Young-Sub You, Gyeonggi-do (KR); Jung-Hwan Oh, Gyeonggi-do (KR); Yong-Woo Hyung, Gyeonggi-do (KR); Hun-Hyoung Lim, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/187,103

(22) Filed: Aug. 6, 2008

Related U.S. Application Data
(63) Continuation-in-part of application No. 11/222,363, filed on Sep. 8, 2005.

(30) Foreign Application Priority Data
May 2, 2005 (KR) 2005-36632

(51) Int. Cl. H01L 27/146; H01L 21/28

(52) U.S. Cl. 257/292; 438/585; 257/E21.177; 257/E27.133

(57) ABSTRACT

A CMOS image sensor includes an image transfer transistor therein. This image transfer transistor includes a semiconductor channel region of first conductivity type and an electrically conductive gate on the semiconductor channel region. A gate insulating region is also provided. The gate insulating region extends between the semiconductor channel region and the electrically conductive gate. The gate insulating region includes a nitridated insulating layer extending to an interface with the electrically conductive gate and a substantially nitrogen-free insulating layer extending to an interface with the semiconductor channel region. The nitridated insulating layer may be a silicon oxynitride (SiON) layer.

### CROSS-REFERENCE TO RELATED APPLICATIONS

This application is a Continuation-In-Part of U.S. patent application Ser. No. 11/222,363, entitled “CMOS IMAGE SENSORS AND METHODS OF FABRICATING SAME,” filed on Sep. 8, 2005.

### BACKGROUND

1. Field

Example embodiments relate to integrated circuit devices and, more particularly, to integrated circuit image sensors and methods of forming integrated circuit image sensors.

2. Description of the Related Art

CMOS image sensors typically include a two-dimensional array of image sensor cells containing image transfer transistors therein. These image sensor transistors are configured to control transfer of photo-generated electron-hole pairs that are accumulated during an image sensing time interval. As illustrated by FIG. 1, a conventional CMOS image sensor cell 10 includes a photodiode (P/D), an image transfer transistor TX, a reset transistor RX, a select transistor SX and an access transistor AX, connected as illustrated. The gate terminal of the select transistor SX is connected to a floating diffusion region (F/D). This floating diffusion region F/D receives charge carriers from the photodiode P/D upon enablement of the image transfer transistor TX. These charge carriers are generated when photon radiation is received by the photodiode P/D and electron-hole pairs are generated therein. The charge carriers accumulated in the floating diffusion region F/D operate to bias the gate terminal of the select transistor SX. In addition, enablement of the reset transistor RX operates to reset the floating diffusion region F/D by electrically coupling this region to a positive power supply voltage VDD.

Data, which is reflected by a quantity of charge carriers accumulated in the floating diffusion region F/D, may operate to render the select transistor SX conductive to thereby connect the power supply voltage line VDD to a current carrying terminal of the access transistor AX. The access transistor AX, which is rendered conductive upon receipt of an active high voltage on a corresponding row line (ROW), operates to pass the power supply voltage VDD to an output line (OUT) when both the select transistor SX and the access transistor AX are conductive. To provide high image quality, it is often necessary to have a high degree of charge carrier transfer from the photodiode P/D to the floating diffusion region F/D when the image transfer transistor TX is rendered conductive. This high degree of charge carrier transfer is necessary in order to prevent an occurrence of ghost imaging or random noise (i.e., image lag). Ghost imaging may occur when charge carriers generated by the photodiode P/D remain within the photodiode P/D after the image transfer transistor is turned off. This residue of charge carriers typically influences a next immediate collection of photons by the photodiode P/D (e.g., during a next frame of a display/image sequence) and may result in the formation of image artifacts that reduce image quality.

### SUMMARY

Embodiments of the invention include an image sensing device having an image transfer transistor therein. This image transfer transistor includes a semiconductor channel region of first conductivity type and an electrically conductive gate on the semiconductor channel region. A gate insulating region is also provided. The gate insulating region extends between the semiconductor channel region and the electrically conductive gate. The gate insulating region includes a nitridated insulating layer extending to an interface with the electrically conductive gate and a substantially nitrogen-free insulating layer extending to an interface with the semiconductor channel region. This substantially nitrogen-free insulating layer may have a concentration of nitrogen that is less than about 1% by weight. In some of these embodiments, the nitridated insulating layer includes silicon oxynitride (SiON), which may be formed by nitridating an upper surface of a silicon dioxide layer. The gate insulating region may have a thickness in a range from about 30 Å to about 100 Å.

Additional image sensing devices according to embodiments of the invention include a semiconductor region having a photodiode therein and an image transfer transistor on the semiconductor region. This image transfer transistor includes a semiconductor channel region of first conductivity type electrically coupled to the photodiode. An electrically conductive gate is provided on the semiconductor channel region. A gate insulating region is also provided that extends between the semiconductor channel region and the electrically conductive gate. The gate insulating region includes a nitridated insulating layer extending to an interface with the electrically conductive gate and a substantially nitrogen-free insulating layer extending to an interface with the semiconductor channel region.

Still further embodiments of the invention include a method of forming an image transfer transistor of an image sensing device. This method includes forming a gate insulating region on a semiconductor substrate and then nitridating an upper surface of the gate insulating region. The nitridating step may include performing a decoupled plasma nitridation (DPN) process on the gate insulating region. This DPN process may be performed at room temperature and may be performed in a reaction chamber receiving about equivalent flow rates of nitrogen gas (N₂) and helium gas (He). An electrically conductive gate is then formed on the nitridated upper surface of the gate insulating region. In some of these embodiments, the nitridating step is followed by the step of annealing the gate insulating region in a nitrogen-containing ambient. The step of forming the electrically conductive gate may also be followed by the step of annealing the gate insulating region in a nitrogen-containing ambient.

In still further embodiments of the invention, the step of forming a gate insulating region includes forming a gate oxide layer on the semiconductor substrate using a radical oxidation process. This radical oxidation process may be performed in a reaction chamber receiving hydrogen (H₂) and oxygen (O₂) gases. The radical oxidation process may also be performed at a temperature in a range from about 450° C. to about 950° C. and at a pressure in a range from about 2 Torr to about 5 Torr. Moreover, a ratio of flow rates of the oxygen (O₂) and hydrogen (H₂) may be in a range from about 70 to about 110. In particular, the hydrogen (H₂) and oxygen (O₂) gases may be flowed at rates of about 0.1 sccm and about 9.0 sccm, respectively.

### BRIEF DESCRIPTION OF THE DRAWINGS

Example embodiments will be more clearly understood from the following detailed description taken in conjunction with the accompanying drawings. FIGS. 1 to 9 represent non-limiting, example embodiments as described herein.

FIG. 1 is an electrical schematic of a conventional CMOS image sensor cell;

FIGS. 2A-2E are cross-sectional views of intermediate structures that illustrate methods of forming an image transfer transistor according to embodiments of the present invention;

FIG. 3 is a graph that illustrates reaction chamber temperature as a function of time, during a radical oxidation process;

FIG. 4 is a graph that illustrates reaction chamber temperature as a function of time, during a PNA anneal process;

FIGS. 5A-5D are cross-sectional views of intermediate structures that illustrate methods of forming CMOS image sensors according to embodiments of the present invention;

FIGS. 6A-6B are graphs illustrating random noise characteristics of an image sensing device including a gate structure in accordance with some example embodiments;

FIG. 7 is a graph illustrating random noise characteristics of image sensing devices including gate insulating layers in accordance with some example embodiments, which may vary according to a concentration of nitrogen therein;

FIG. 8 is a graph illustrating threshold voltage characteristics of image sensing devices including gate structures in accordance with some example embodiments; and

FIG. 9 is a graph illustrating a distribution of a nitridated insulating layer in a gate insulating region, which is formed by a plasma nitridation process in accordance with some example embodiments.

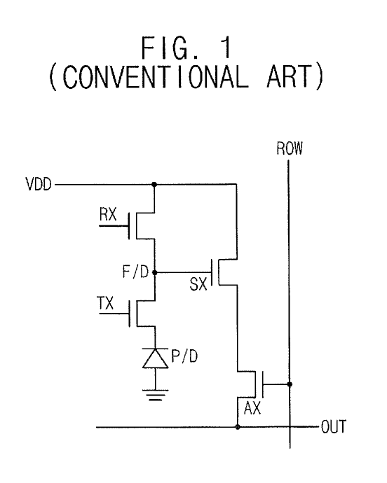

### DETAILED DESCRIPTION OF THE EMBODIMENTS

This application claims priority under 35 USC § 119 to Korean Patent Application No. 2005-36632, filed on May 2, 2005 in the Korean Intellectual Property Office (KIPO), the contents of which are herein incorporated by reference in their entirety.

Various example embodiments will be described more fully hereinafter with reference to the accompanying drawings, in which some example embodiments are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

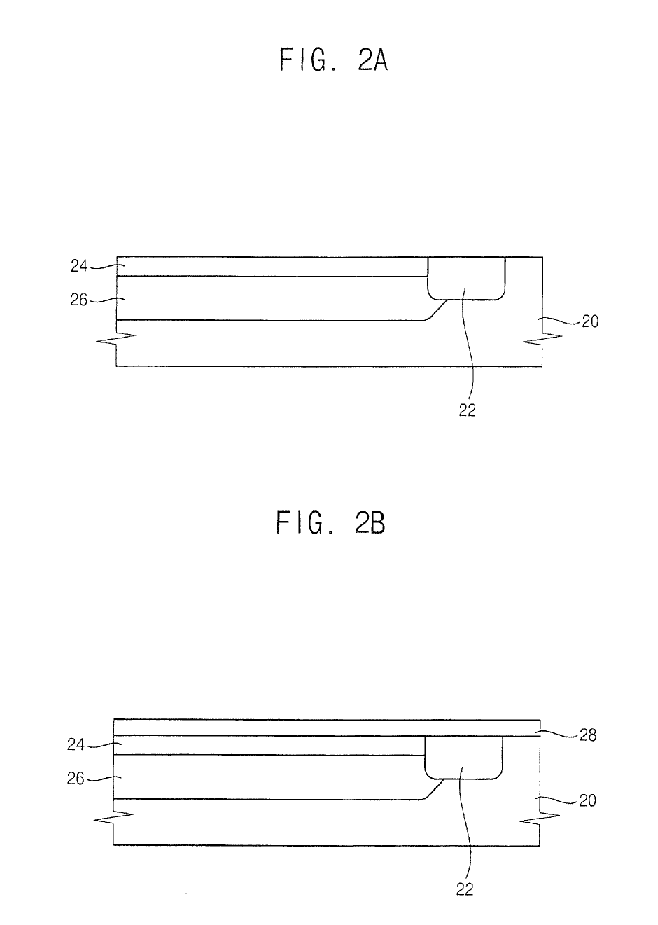

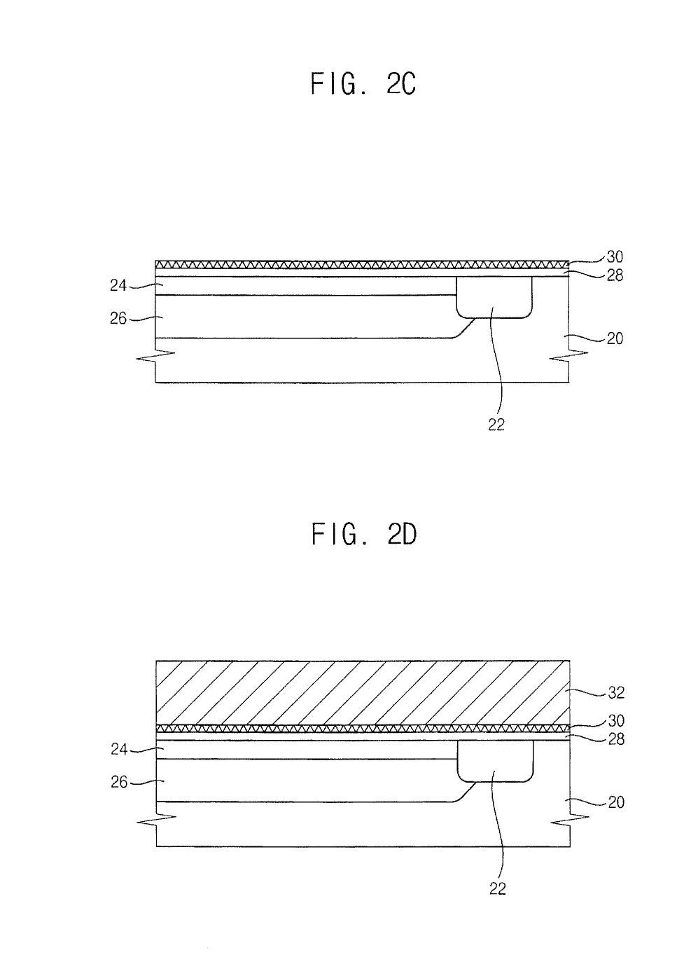

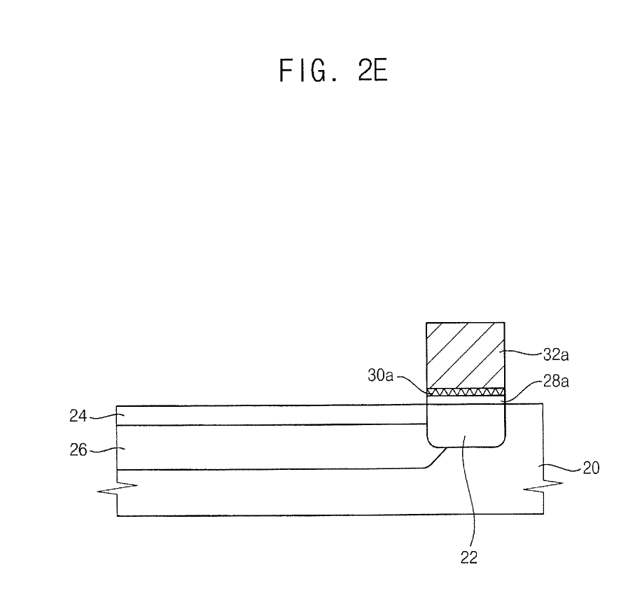

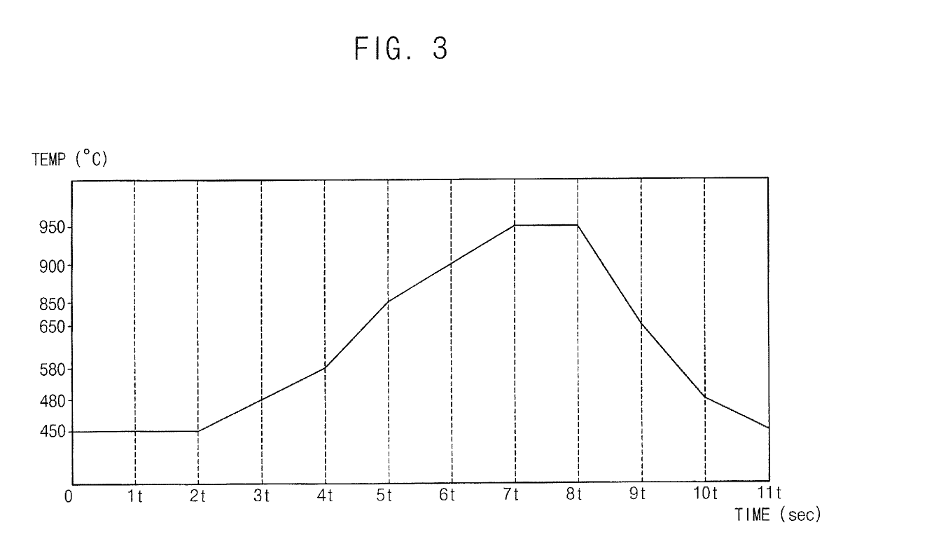

As illustrated by FIG. 2A, methods of forming an image transfer transistor according to embodiments of the present invention include forming a channel region 22 in a semiconductor substrate 20. This channel region 22 may be formed as a P-type region in the event the image transfer transistor is an NMOS transistor or an N-type region in the event the image transfer transistor is a PMOS transistor. The channel region 22 is electrically coupled to a photodiode P/D. This photodiode includes a P-type region 24 (anode) and an N-type region 26 (cathode). The P-type region 24 may be formed by implanting B or BF2 into the substrate 20 and the N-type region 26 may be formed by implanting P or As into the substrate 20. As illustrated by FIG. 2B, a gate insulating layer 28 may be formed on an upper surface of the substrate 20. This gate insulating layer 28 may be formed by a thermal oxidation process, chemical vapor deposition (CVD) or a radical oxidation process. The gate insulating layer 28 may be formed to a thickness in a range between about 30 Å and about 100 Å. A radical oxidation process may be performed in a reaction chamber receiving hydrogen (H₂) and oxygen (O₂) gases and may be performed at a temperature in a range from about 450° C. to about 950° C. As illustrated by FIG. 3, the temperature in the reaction chamber during radical oxidation may vary as a function of time from a lower temperature of 450° C. to a maximum temperature of 950° C., during a time interval from 0 t to 11 t, where “t” represents a value that may vary in the event the time intervals from 0 to 11 t are non-uniform. During the radical oxidation process, the chamber may be maintained at a pressure in a range from about 2 Torr to about 5 Torr. The hydrogen (H₂) and oxygen (O₂) gases may also be flowed at rates that achieve an oxygen-to-hydrogen rate ratio in a range from about 70 to about 110. In particular, the hydrogen (H₂) and oxygen (O₂) gases may be flowed at rates of about 0.1 sccm and about 9.0 sccm, respectively.

Referring now to FIG. 2C, a thin nitride layer 30 (a nitridated insulating layer) is formed directly on the gate insulating layer 28. This thin nitride layer 30 may be formed within a process chamber using a decoupled plasma nitridation (DPN) process that may convert an upper surface region of silicon dioxide (SiO₂) within the gate insulating layer 28 to silicon oxynitride (SiON). Although not wishing to be bound by any theory, it is believed that this thin nitride layer operates as a dopant barrier (e.g., boron diffusion blocking layer), which blocks out-diffusion of dopants from a subsequently formed gate layer, improves the noise characteristics of the image transfer transistor and inhibits ghost imaging. This DPN process may include flowing N2 and H2 gases at room temperature and at rates equivalent to 100 sccm and 100 sccm, respectively, with a constant chamber pressure of 80 mTorr and a chamber RF power of 500 W. This thin nitride layer 30 may be formed to a thickness in a range between about 1 Å and about 10 Å. This DPN process may be performed across a series of time intervals including an initial stabilization time interval (duration=10 sec.), a strike time interval (duration=5 sec.), a nitridation time interval (duration=60 sec.), a dechuck time interval (duration=5 sec.) and a final purge time interval (duration=5 sec.). The stabilization and purge time intervals may be performed at an RF power of 0 W and the strike, nitridation and dechuck time intervals may be performed at an RF power of 500 W. The DPN process may be followed by an annealing step performed within the process chamber receiving nitrogen and oxygen gases maintained at a pressure of 5 Torr.

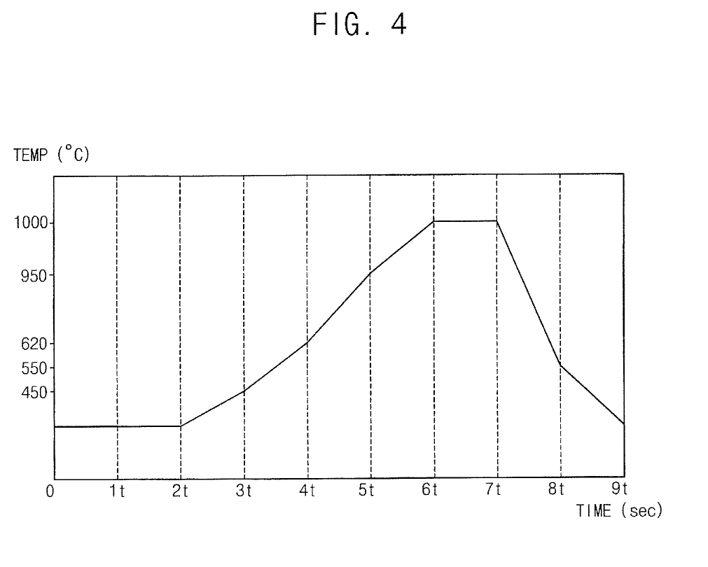

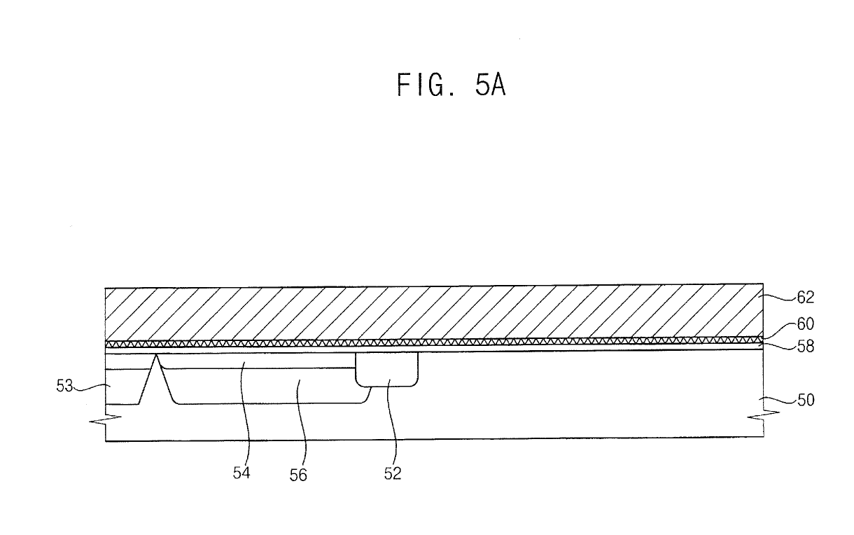

As illustrated by FIG. 4, during a post-nitridation anneal (PNA), the temperature in the reaction chamber may vary as a function of time from a lower temperature of 450° C. to a maximum temperature of 1,000° C., during a time interval from 0 t to 9 t, where “t” represents a value that may vary in the event the time intervals from 0 to 9 t are non-uniform. In some embodiments, the PNA step may be performed after a subsequent step of forming an electrically conductive gate layer on the gate insulating layer. An electrically conductive gate layer 32 is formed on the thin nitride layer 30, as illustrated by FIG. 2D. This electrically conductive gate layer 32 may be formed of polycrystalline silicon, for example. Referring now to FIG. 2E, the gate layer 32, nitride layer 30 and gate insulating layer 28 are then photolithographically patterned as regions 32a, 30a and 28a to define an insulated gate electrode of the image transfer transistor.

The gate insulating layer 28 of the image transfer transistor TX in accordance with some example embodiments does not substantially include nitrogen; that is, the gate insulating layer 28 is a substantially nitrogen-free insulating layer. The gate insulating layer 28 may have a nitrogen concentration of less than about 1% by weight. In an example embodiment, the gate insulating layer 28 has a nitrogen concentration of about 0.5%. In another example embodiment, the gate insulating layer 28 has a nitrogen concentration of about 0.4%.

The thin nitride layer 30 is formed on the gate insulating layer 28 so that the change of the threshold voltage characteristics of the image transfer transistor TX, which is generated by boron penetration from the electrically conductive gate layer 32 into the channel region 22, may be prevented. However, the thin nitride layer 30 does not extend to an interface with the channel region 22. That is, the gate insulating layer 28 adjacent to the channel region 22 does not substantially include nitrogen, and thus the occurrence of the random noise of the image sensing device including the image transfer transistor TX may be reduced.

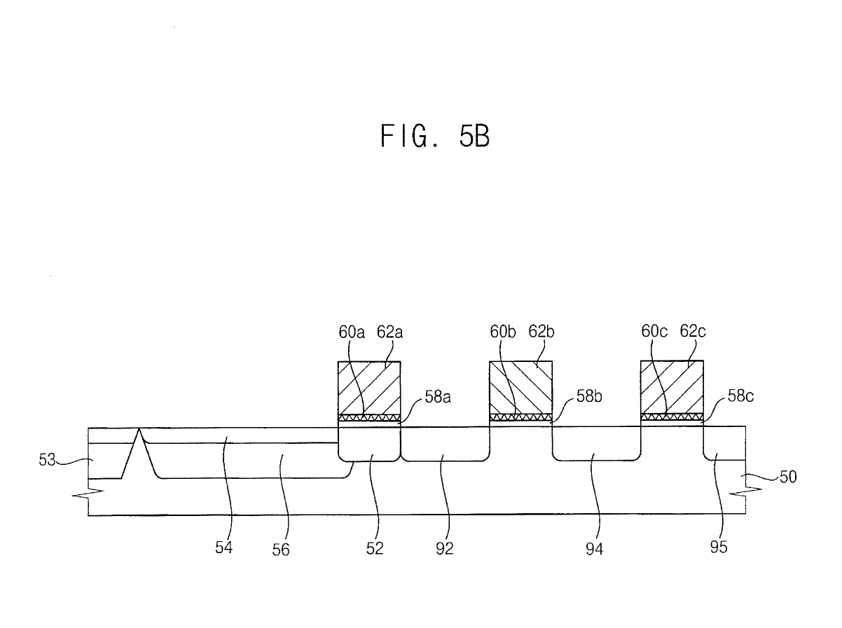

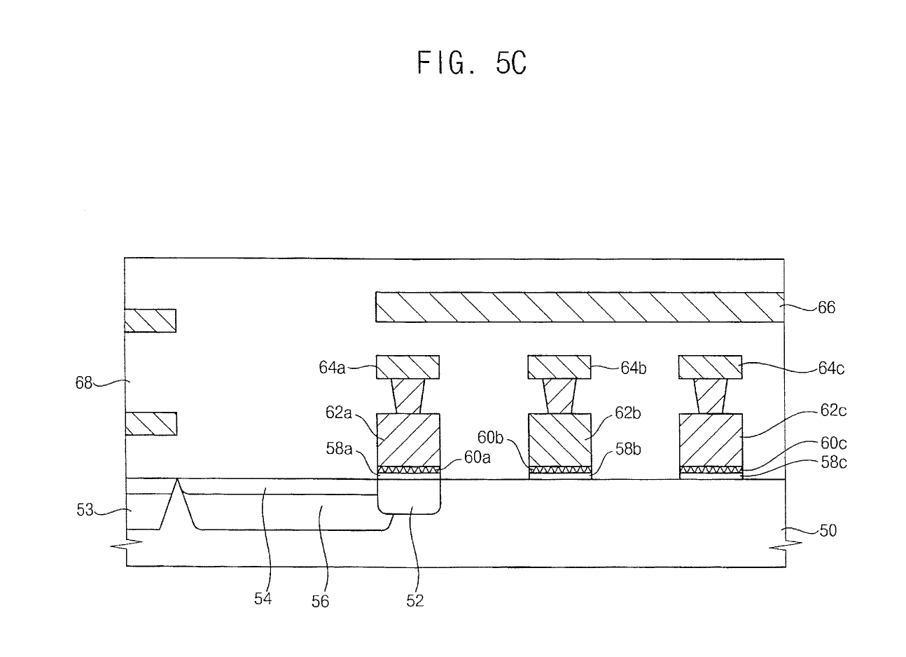

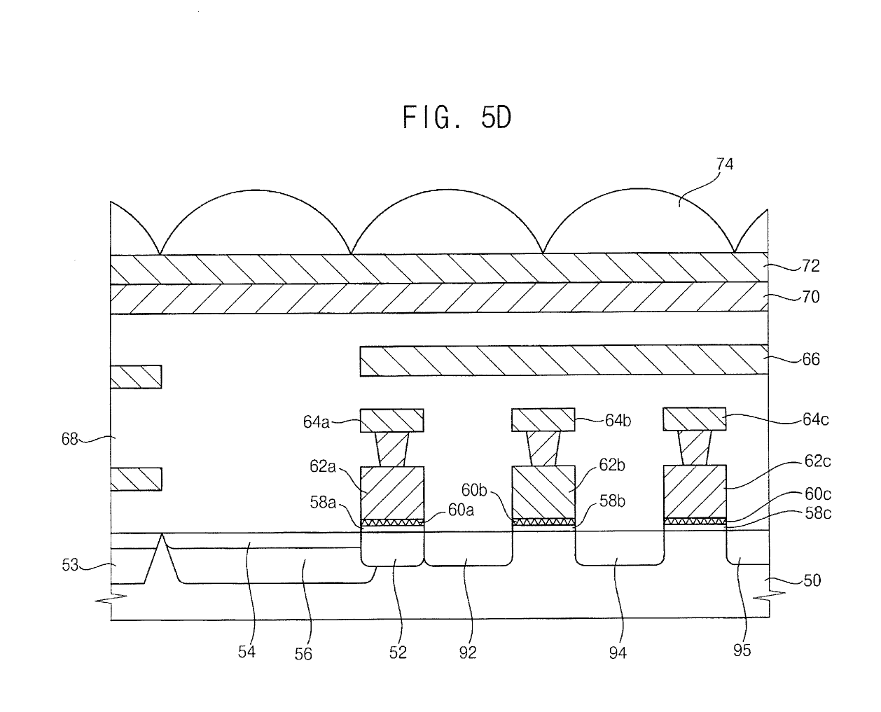

Referring now to FIGS. 5A-5D, methods of forming image sensor devices include forming a trench isolation region 53 and a channel region 52 of first conductivity type in a semiconductor substrate 50. This channel region 52 may be formed as a P-type region in the event the sensor uses NMOS image transfer transistors or an N-type region in the event the sensor uses PMOS image transfer transistors. A photodiode is also formed adjacent the channel region 52. This photodiode is formed as a P-N junction within the substrate 50. This P-N junction includes a P-type region 54 and an N-type region 56. Typical P-type dopants include B and BF2 and typical N-type dopants include As and P. A gate insulating layer 58 is formed on a surface of the substrate 50. This gate insulating layer 58 may be formed using a thermal oxidation process, a chemical vapor deposition (CVD) process or a radical oxidation process, as described above with respect to FIGS. 2A-2E. The gate insulating layer 58 may be formed to a thickness in a range between about 30 Å and about 100 Å. Thereafter, a thin nitride layer 60 is formed directly on the gate insulating layer 58. This thin nitride layer 60 may be formed within a process chamber using a decoupled plasma nitridation (DPN) process that may convert silicon dioxide (SiO₂) within the gate insulating layer 58 to silicon oxynitride (SiON).

This DPN process may include flowing N2 and H2 gases at room temperature and at rates equivalent to 100 sccm and 100 sccm, respectively, with a constant chamber pressure of 80 mTorr and a chamber RF power of 500 W. This thin nitride layer 60 may be formed to a thickness in a range between about 1 Å and about 10 Å. This DPN process may be performed across a series of time intervals including an initial stabilization time interval (duration=10 sec.), a strike time interval (duration=5 sec.), a nitridation time interval (duration=60 sec.), a dechuck time interval (duration=5 sec.) and a final purge time interval (duration=5 sec.). The stabilization and purge time intervals may be performed at an RF power of 0 W and the strike, nitridation and dechuck time intervals may be performed at an RF power of 500 W. The DPN process may be followed by an annealing step performed within the process chamber receiving nitrogen and oxygen gases maintained at a pressure of 5 Torr. As illustrated by FIG. 4, during a post-nitridation anneal (PNA), the temperature in the reaction chamber may vary as a function of time from a lower temperature of 450° C. to a maximum temperature of 1,000° C., during a time interval from 0 t to 9 t, where “t” represents a value that may vary in the event the time intervals from 0 to 9 t are non-uniform. An electrically conductive gate layer 62 is then formed on the thin nitride layer 60. This electrically conductive gate layer 62 may be formed of polycrystalline silicon, for example.

Referring now to FIG. SB, the electrically conductive gate layer 62 and the gate insulating layer 58 are then photolithographically patterned to define a gate electrode of an image transfer transistor TX (regions 62a, 60a and 58a), a gate electrode of a reset transistor RX (regions 62b, 60b and 58b) and a gate electrode of a select transistor SX (regions 62c, 60c and 58c). Thereafter a plurality of metal lines 64a, 64b and 64c are formed on corresponding gate electrodes, as illustrated by FIG. 5C. A metal line 66 may also be formed as a light blocking shield within an interlayer insulating layer 68, which may be formed using a CVD process.

Referring now to FIG. 5D, a color filter 70, over coating layer 72 and micro lens array 74 may be formed on the interlayer insulating layer 68 using conventional techniques. Further passivation (not shown) may also be provided on the micro lens array 74.

The gate insulating layer 58 of the image sensing device in accordance with some example embodiments does not substantially include nitrogen; that is, the gate insulating layer 58 is a substantially nitrogen-free insulating layer. The gate insulating layer 58 may have a nitrogen concentration of less than about 1% by weight. In an example embodiment, the gate insulating layer 58 has a nitrogen concentration of about 0.5%. In another example embodiment, the gate insulating layer 58 has a nitrogen concentration of about 0.4%.

The thin nitride layer 60 is formed on the gate insulating layer 38 so that the change of the threshold voltage characteristics of the image sensing device due to the boron penetration may be prevented. However, the thin nitride layer 60 does not extend to an interface with the channel region 52. That is, the gate insulating layer 58 adjacent to the channel region 52 does not substantially include nitrogen, and thus the occurrence of the random noise of the image sensing device including the image transfer transistor TX may be reduced.

### Evaluation of Random Noise Characteristics 1

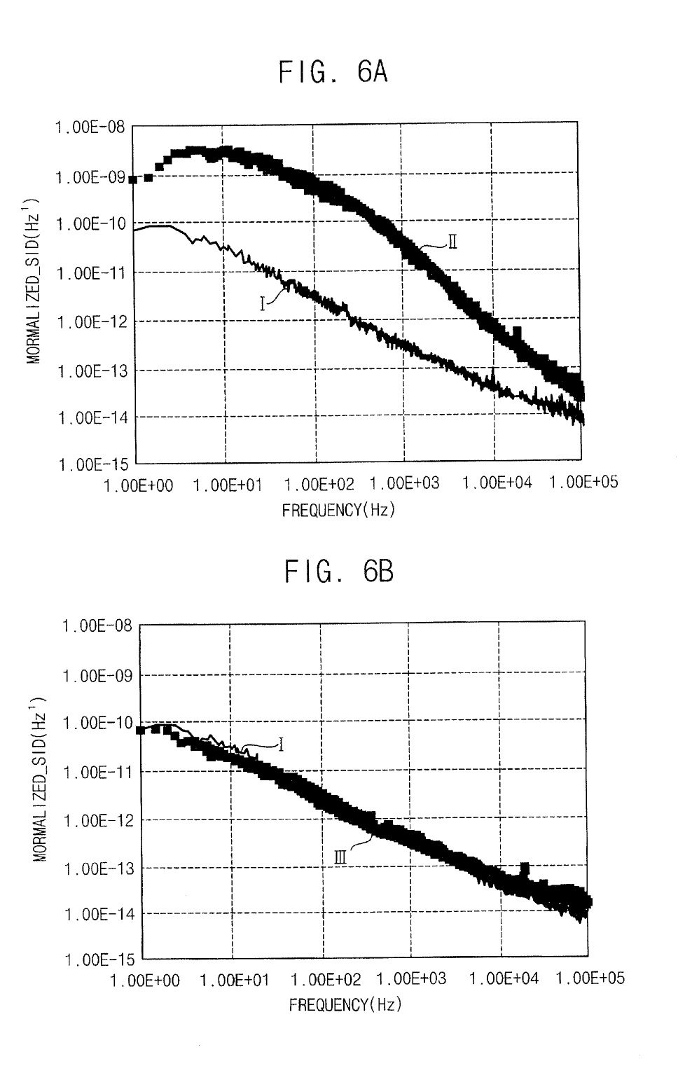

FIGS. 6A-6B are graphs illustrating random noise characteristics of an image sensing device including a gate structure in accordance with some example embodiments. In FIGS. 6A-6B, Curve I indicates random noise characteristics of an image sensing device having a gate insulating layer formed by a radical oxidation process (Comparative Example 1), Curve II indicates random noise characteristics of an image sensing device having a gate insulating layer including silicon oxynitride (Comparative Example 2), and Curve III indicates random noise characteristics of an image sensing device having a nitride layer on an upper surface of a gate insulating layer in accordance with Example 1.

In order to grasp the random noise characteristics, a drain-source voltage V_{DS} of about 2.8 V and a gate-source voltage V_{GS} of about 2.0 V were applied to the gate structures of Example 1 and Comparative Examples 1 and 2, respectively. Particularly, the image sensing device of Example 1 had a nitride layer formed by a DPN process performed at a temperature of about 23° C. at a power of about 500 W.

Referring to FIGS. 6A-6B, the image sensing device of Comparative Example 1 has much less random noise than the image sensing device of Comparative Example, and the image sensing device of Example 1 has very similar random noise to the image sensing device of Comparative Example 1.

Thus, the image sensing device having the nitride layer between the electrically conductive gate layer and the gate insulating layer may have random noise characteristics better than those of the image sensing device having a gate insulating layer including silicon oxynitride, and similar to those of the image sensing device having a gate insulating layer including silicon oxide.

### Evaluation of Random Noise Characteristics 2

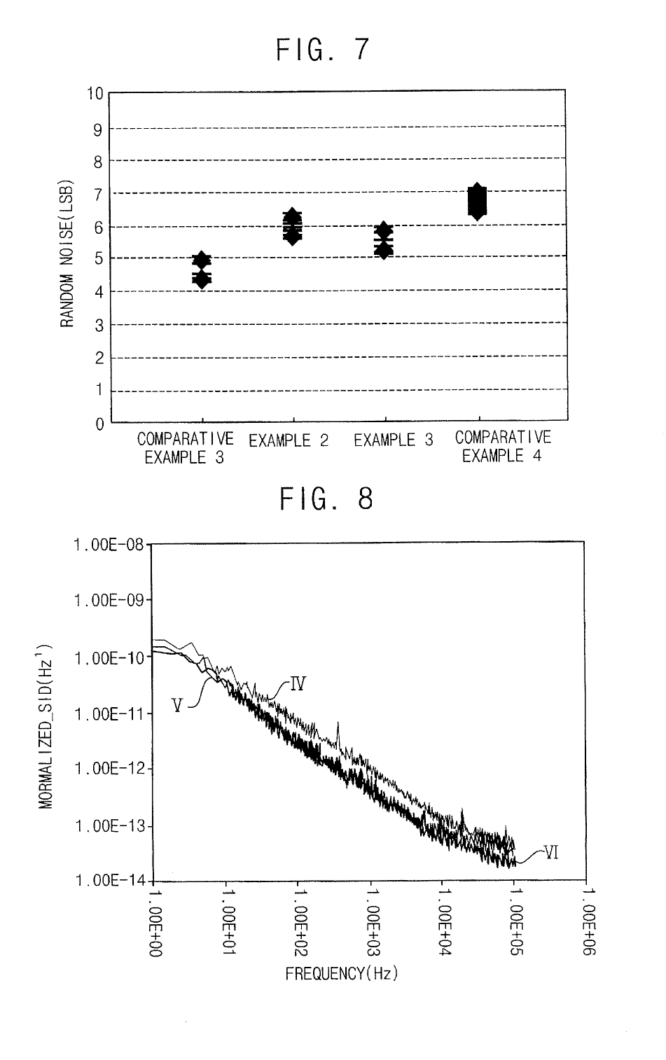

FIG. 7 is a graph illustrating random noise characteristics of image sensing devices including gate insulating layers in accordance with some example embodiments, which may vary according to a concentration of nitrogen therein. In FIG. 7, Comparative Example 3 indicates an image sensing device having a gate insulating layer including silicon oxide formed by a radical oxidation process, Comparative Example 4 indicates an image sensing device having a gate insulating layer including silicon oxynitride having a nitrogen concentration of about 1.95%. Examples 2 and 3 indicate image sensing devices, each of which has a nitride layer between an electrically conductive gate layer and a gate insulating layer. Particularly, the image sensing device of Example 2 was formed by performing a heat treatment on a gate insulation layer of Comparative Example 3 using nitric oxide (NO) gas, and thus the gate insulating layer had a nitrogen concentration of about 0.5%. The image sensing device of Example 3 was formed by performing a heat treatment on a gate insulation layer of Comparative Example 3 using nitrogen (N₂) gas, and thus the gate insulating layer had a nitrogen concentration of about 0.4%.

Referring to FIG. 7, the image sensing devices in accordance with Examples 2 and 3 have random noise characteristics better than those of the image sensing device of Comparative Example 4.

### Evaluation of Threshold Voltage Characteristics

FIG. 8 is a graph illustrating threshold voltage characteristics of image sensing devices including gate structures in accordance with some example embodiments. In FIG. 8, Curve IV indicates threshold voltage characteristics of an image sensing device having a gate insulating layer including silicon oxynitride (Comparative Example 5), Curves V and VI indicate threshold voltage characteristics of image sensing devices having nitride layers on gate insulating layers, each of which were formed by a DPN process (Examples 4 and 5). Particularly, the DPN process in Example 4 was performed at a temperature of about 23° C. at a power of about 100 W, and the DPN process in Example 5 was performed at a temperature of about 23° C. at a power of about 900 W.

In order to grasp the random noise characteristics, a drain-source voltage V_{DS} of about 2.8 V and a gate-source voltage V_{GS} of about 2.0 V were applied to the gate structures of Examples 4 and 5 and Comparative Example 5, respectively.

Referring to FIG. 8, the image sensing devices of Examples 4 and 5 and Comparative Example 5 have threshold voltage characteristics similar to one another. Thus, even though the nitride layer is formed on the gate insulating layer in the gate structure, the gate structure may have good threshold voltage characteristics because the boron penetration may be prevented.

### Evaluation of Distribution of a Nitridated Insulating Layer

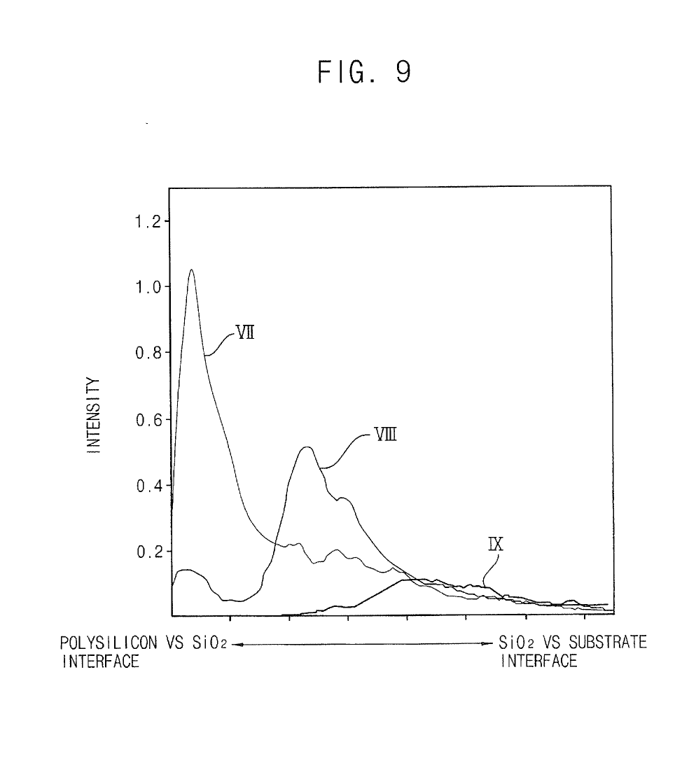

FIG. 9 is a graph illustrating a distribution of a nitridated insulating layer in a gate insulating region, which is formed by a plasma nitridation process in accordance with some example embodiments. In FIG. 9, Curve VII indicates a distribution of a nitridated insulating layer formed by performing a DPN process on a gate insulating layer including silicon oxide at a temperature of about 23° C. at a power of about 500 W (Example 6). Curve VIII indicates a distribution of a nitridated insulating layer formed by performing a DPN process on a gate insulating layer including silicon oxide at a temperature of about 800° C. (Comparative Example 6). The DPN process used in Comparative Example 6 is similar to that disclosed in Korean Laid-Open Patent Publication No. 2004-7968. Curve IX indicates a distribution of a nitridated insulating layer formed by performing a DPN process on a gate insulating layer including silicon oxynitride at a temperature of about 800° C. (Comparative Example 7). The distributions of the nitridated insulating layers of Example 6 and Comparative Examples 6 and 7 were measured by secondary ion mass spectroscopy (SIMS).

Referring to FIG. 9, the nitridated insulating layer of Example 6 is concentratedly distributed at the interface between an electrically conductive gate layer including polysilicon and a gate insulating layer including silicon oxide.

According to some example embodiments, by concentratedly forming a nitridated insulating layer at/on an upper surface of a gate insulating layer, boron penetration may be prevented so that threshold voltage characteristics may not be changed, without having an influence on random noise characteristics. Therefore, an image sensing device may have good electrical characteristics.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. An image transfer transistor of an image sensing device, comprising:
a semiconductor channel region of first conductivity type;
an electrically conductive gate on said semiconductor channel region; and
a gate insulating region extending between said semiconductor channel region and said electrically conductive gate, said gate insulating region comprising a nitridated insulating layer extending to an interface with said electrically conductive gate and a substantially nitrogen-free insulating layer extending to an interface with said semiconductor channel region.

2. The image transfer transistor of claim 1, wherein the nitridated insulating layer comprises silicon oxynitride (SiON).

3. The image transfer transistor of claim 1, wherein said electrically conductive gate comprises a polysilicon region of first conductivity type.

4. The image transfer transistor of claim 2, wherein said gate insulating region has a thickness in a range from about 30 Å to about 100 Å.

5. The image transfer transistor of claim 1, wherein said gate insulating region comprises a silicon dioxide layer having a nitridated upper surface.

6. The image transfer transistor of claim 1, wherein a percentage of nitrogen in the substantially nitrogen-free insulating layer is less than about 1%.

7. An image sensing device, comprising:
a semiconductor region having a photodiode therein; and
an image transfer transistor on said semiconductor region, said image transfer transistor comprising:
a semiconductor channel region of first conductivity type electrically coupled to the photodiode;
an electrically conductive gate on the semiconductor channel region; and
a gate insulating region extending between the semiconductor channel region and the electrically conductive gate, said gate insulating region comprising a nitridated insulating layer extending to an interface with the electrically conductive gate and a substantially nitrogen-free insulating layer extending to an interface with the semiconductor channel region.

8. The device of claim 7, wherein the nitridated insulating layer comprises silicon oxynitride (SiON).

9. The device of claim 7, wherein said electrically conductive gate comprises a polysilicon region of first conductivity type.

10. The device of claim 8, wherein said gate insulating region has a thickness in a range from about 30 Å to about 100 Å.

11. The device of claim 7, wherein said gate insulating region comprises a silicon dioxide layer having a nitridated upper surface.

12. The image transfer transistor of claim 7, wherein a percentage of nitrogen in the substantially nitrogen-free insulating layer is less than about 1%.

13. A method of forming an image transfer transistor of an image sensing device, comprising the steps of:
forming a gate insulating region on a semiconductor substrate;
nitridating an upper surface of the gate insulating region; and
forming an electrically conductive gate on the nitridated upper surface of the gate insulating region.

14. The method of claim 13, wherein said nitridating step is followed by the step of annealing the gate insulating region in a nitrogen-containing ambient.

15. The method of claim 13, wherein said step of forming the electrically conductive gate is followed by the step of annealing the gate insulating region in a nitrogen-containing ambient.

16. The method of claim 13, wherein said nitridating step comprises performing a decoupled plasma nitridation (DPN) process on the gate insulating region.

17. The method of claim 16, wherein the DPN process is performed at about room temperature.

18. The method of claim 16, wherein the DPN process is performed in a reaction chamber receiving about equivalent flow rates of nitrogen gas (N₂) and helium gas (He).

19. The method of claim 16, wherein the DPN process comprises powering a nitrogen plasma at about 500 W.

20. The method of claim 13, wherein said step of forming a gate insulating region comprises forming a gate oxide layer on the semiconductor substrate using a radical oxidation process.

21. The method of claim 20, wherein the radical oxidation process is performed in a reaction chamber receiving hydrogen (H₂) and oxygen (O₂) gases.

22. The method of claim 21, wherein the radical oxidation process is performed at a temperature in a range from about 450° C. to about 950° C.

23. The method of claim 22, wherein the radical oxidation process is performed at a pressure in a range from about 2 Torr to about 5 Torr.

24. The method of claim 22, wherein the hydrogen (H₂) and oxygen (O₂) gases are flowed at rates of about 0.1 sccm and about 9.0 sccm, respectively.

25. The method of claim 13, wherein said step of forming a gate insulating region comprises forming a gate oxide layer substantially free of nitrogen on the semiconductor substrate.

26. The method of claim 22, wherein a ratio of flow rates of the oxygen (O₂) and hydrogen (H₂) is in a range from about 70 to about 110.
